(19) United States
(12) Patent Application Publication
(10) Pub. No.: US 2003/0237036 A1
(43) Pub. Date: Dec. 25, 2003

(54) Semiconductor integrated circuit with built-in self-test function and system including the same

(76) Inventor: Kenji Kimura, Tokyo (JP)

Correspondence Address: BURNS, DOANE, SWECKER & MATHIS, L.L.P., P.O. Box 1404, Alexandria, VA, 22313-1404, US

(21) Appl. No.: 10/320,618

(22) Filed: Dec. 17, 2002

(30) Foreign Application Priority Data
Jun. 19, 2002 (JP) 2002-178872

(51) Int. Cl. G01R 31/28

(52) U.S. Cl. 714/733

(57) ABSTRACT

A semiconductor integrated circuit with built-in self-test function includes an I/O port which is connected to a pad and constituted of a port direction register; a port register; and a comparator, and a peripheral function block connected to the pad, and when it is intended to test an output of the peripheral function block, the semiconductor integrated circuit with built-in self-test function performs a test judgment by setting an expected value for the output of the peripheral function block in the port register, setting a value for setting the I/O port as an input port in the port direction register and making a comparison between a value output from the peripheral function block via the pad and the expected value set in the port register with the comparator.

### BACKGROUND OF THE INVENTION

1. Field of the Invention

The present invention relates to a semiconductor integrated circuit with built-in self-test function and a system including the same.

2. Description of Related Art

In conventional micro processors, a test accompanied by external input and output is being performed by using a semiconductor tester, and with speedup of micro processors in recent years, a high-speed and costly semiconductor tester becomes needed and a test cost has been increased.

Therefore, a semiconductor integrated circuit with built-in self-test function in which a test circuit is provided inside the micro processor is made up in some cases.

Because the conventional semiconductor integrated circuit with built-in self-test function is made up as above, a scale of the test circuit provided inside the micro processor raises a problem. And because specifically a large-scale test circuit is needed for a sufficient test on logic of the micro processor, this causes a problem that the constitution of micro processor is upsized.

Further, there arises another problem that it is difficult to test a micro processor integrated in a system after shipment.

### SUMMARY OF THE INVENTION

The present invention is intended to solve the above described problems and it is an object of the present invention to provide a semiconductor integrated circuit with built-in self-test function which allows a self-test on a peripheral function block by additionally providing a small scale circuit and achieves reduction in test cost and a fail safe on products, and a system including the same.

The semiconductor integrated circuit with built-in self-test function in accordance with the present invention is made to perform a test judgment when it is intended to test an output of the peripheral function block, by setting an expected value for the output of the peripheral function block in the port register, and at the same time setting a value for setting the I/O port as an input port in the port direction register and making a comparison between a value output from the peripheral function block via the terminal and the expected value set in the port register with the comparator.

Therefore, by this arrangement the present invention produces an effect of achieving a self-test on a multifunction semiconductor integrated circuit without utilizing an expensive tester to realize a reduction in test cost.

The system including a semiconductor integrated circuit with built-in self-test function in accordance with the present invention, the semiconductor integrated circuit with built-in self-test function is incorporated therein and is made to perform a test on a peripheral function block which the semiconductor integrated circuit with built-in self-test function itself includes when the system is powered-up, reset, under a judgment of abnormal condition or under diagnostics to realize a fail safe function by an early detection of abnormal operation, output of a signal notifying an operation halt due to detection of abnormal condition or a signal notifying an upper level control block of an abnormal condition, or any combination thereof.

Therefore, by this arrangement the present invention produces an effect of obtaining a system which achieves a fail safe function.

### BRIEF DESCRIPTION OF THE DRAWINGS

FIG. 1 is a block diagram to show a constitution of a semiconductor integrated circuit with built-in self-test function in accordance with a first preferred embodiment of the present invention;

FIG. 2 is a timing chart to show an operation of the semiconductor integrated circuit with built-in self-test function in accordance with the first preferred embodiment of the present invention;

FIG. 3 is a block diagram to show problems a semiconductor integrated circuit in the prior art technology;

FIG. 4 is a timing chart to show problems of the semiconductor integrated circuit in the prior art technology; and

FIG. 5 is a block diagram to show a constitution of a semiconductor integrated circuit with built-in self-test function in accordance with a fifth preferred embodiment of the present invention.

### DETAILED DESCRIPTION OF THE PREFERRED EMBODIMENTS

Now, preferred embodiments of the present invention will be discussed with reference to the attached drawings.

The First Preferred Embodiment

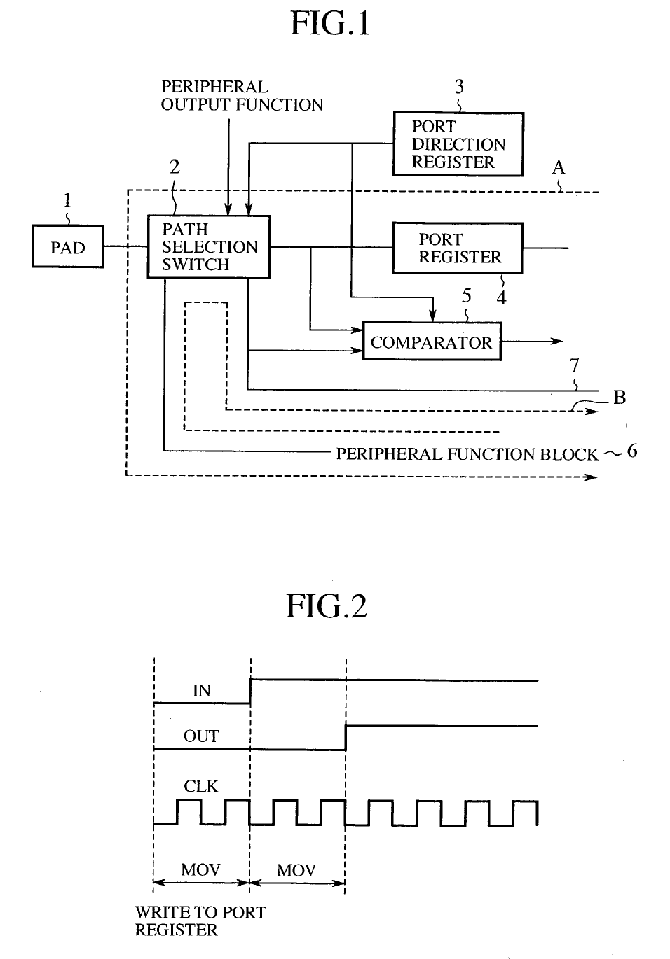

FIG. 1 is a block diagram to show a constitution of a semiconductor integrated circuit with built-in self-test function in accordance with a first preferred embodiment of the present invention. In FIG. 1, reference numeral 1 denotes a pad (terminal), 2 denotes a path selection switch, 3 denotes a port direction register, 4 denotes a port register and 5 denotes a comparator. The port direction register 3, the port register 4 and the comparator 5 constitute an I/O port.

Reference numeral 6 denotes a peripheral function block and 7 denotes an input signal line (port input signal line). Reference signs A and B represent paths.

FIG. 2 is a timing chart to show an operation of the semiconductor integrated circuit with built-in self-test function in accordance with the first preferred embodiment of the present invention.

Next, an operation will be discussed.

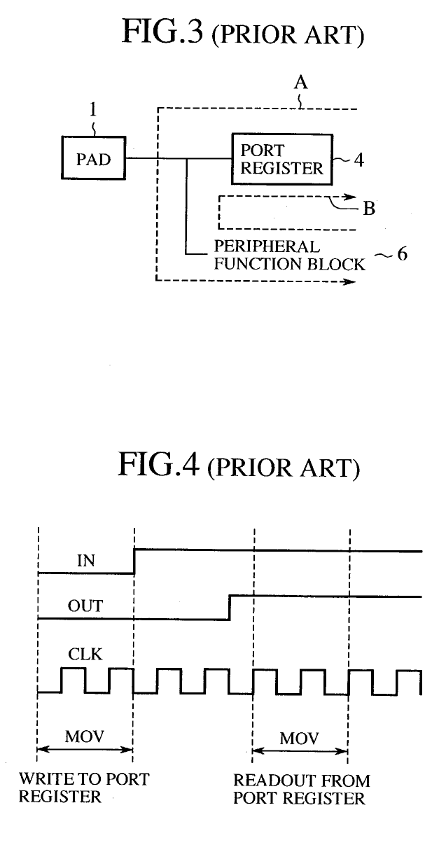

FIGS. 3 and 4 are explanatory illustrations to show problems of a semiconductor integrated circuit in the prior art technology.

When the port register 4 and the peripheral function block 6 are connected to the same pad 1 as shown in FIG. 3, with a command of write to the port register 4, an input is given to the peripheral function block 6 through the path A (IN of FIG. 4). On the other hand, through a readout from the port register 4, an output of the peripheral function block 6 at that time can be read out, via the pad 1, from the input signal line as an input of the port register 4 through the path B (at this time, the port register 4 holds the written value and does not make an update with the readout value), and therefore an output of the peripheral function block 6 can be read out (OUT of FIG. 4)

Since the same port register 4 is used, however, for the input to the peripheral function block 6 and the output from the peripheral function block 6, it is impossible to test the input and output to/from the peripheral function block 6 at the same time. In other words, there is a problem that an output value of the peripheral function block 6 can be tested only during the period of readout from the port register 4.

Then, as shown in FIG. 1, provided are the port direction register 3 for setting the I/O port as an output port or an input port in response to a value set for it and the comparator 5 for comparing an expected value set in the port register 4 with a value output from the peripheral function block 6 to perform a test judgment in response to the value set in the port direction register 3, specifically, when the value set in the port direction register 3 indicates a test of the output from the peripheral function block 6.

When it is intended to give an input to the peripheral function block 6, a value for setting the I/O port as the output port, for example “0”, is set in the port direction register 3 and the value set in the port register 4 is given to the peripheral function block 6 via the pad 1 through the path A. At this time, the comparator 5 is set in a comparison disabling mode in response to the value of “0” set in the port direction register 3.

Further, when it is intended to test an output of the peripheral function block 6, the test judgment is performed by setting an expected value of the output of the peripheral function block 6 in the port register 4, and at, the same time setting a value for setting the I/O port as the input port, for example, “1” in the port direction register 3 and making a comparison between the value output from the peripheral function block 6 via the pad I through the path B and the expected value set in the port register 4 with the comparator 5. At this time, the comparator 5 is set in a comparison enabling mode in response to the value of “1” set in the port direction register 3.

Thus, according to the first preferred embodiment, by distinguishing the values written into the port register 4 between the input values to the peripheral function block 6 and the expected values of output from the peripheral function block 6 as shown in FIG. 2 and always making a comparison between the output value of the peripheral function block 6 and the expected value with the comparator 5 to judge whether these values are equal to each other or not, it is made possible to solve the problem that comparison of the output value from the peripheral function block 6 can be performed only during a period of next readout from the port register 4 and that the input and the output can not be tested at the same time.

Further, for controlling the comparator 5 with the port direction register 3, other signal, for example, indicating the output of the peripheral function block 6 may be used together.

The Second Preferred Embodiment

In the second preferred embodiment, a test judgment result obtained by the comparator 5 is used as an interrupt request to perform an error processing as an interrupt processing in the semiconductor integrated circuit with built-in self-test function of the above discussed first preferred embodiment.

Thus, the error processing can be performed as the interrupt processing and therefore an efficient test judgment is achieved.

The Third Preferred Embodiment

In the third preferred embodiment, the test judgment result obtained by the comparator 5 is output through an external pin to the outside in the semiconductor integrated circuit with built-in self-test function of the above discussed first preferred embodiment.

Thus, the test judgment result can be output to external devices other than the present semiconductor integrated circuit by using the external pin.

The Fourth Preferred Embodiment

In the fourth preferred embodiment, when tests are simultaneously performed on a plurality of I/O ports which can not be accessed at the same time in the semiconductor integrated circuit with built-in self-test function of the above discussed first preferred embodiment, a permission or a non-permission is given to a plurality of I/O ports at the same time with a comparison enabling signal other than the values of the respective port direction registers 3.

Thus, though it is impossible to simultaneously perform tests on a plurality of I/O ports only with the port direction registers 3, it is made possible to simultaneously perform the tests on a plurality of I/O ports by giving permission or non-permission to a plurality of I/O ports at the same time with the comparison enabling signal.

The Fifth Preferred Embodiment

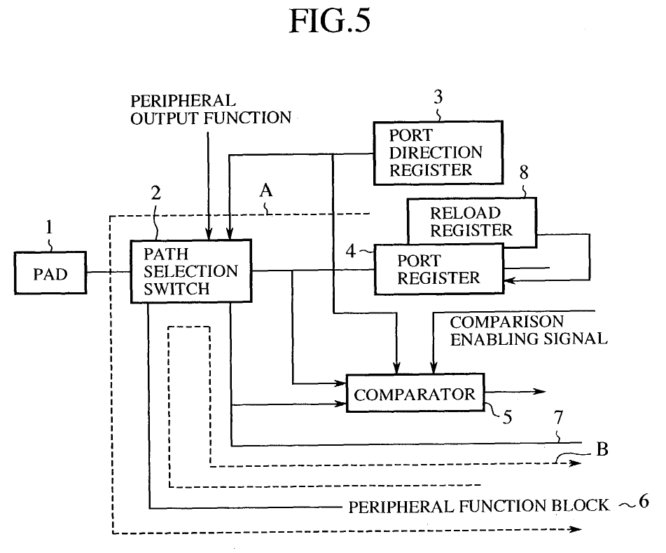

FIG. 5 is a block diagram to show a constitution of a semiconductor integrated circuit with built-in self-test function in accordance with a fifth preferred embodiment of the present invention. In FIG. 5, reference numeral 8 denotes a reload register. Other constituents are quite the same as those of the fourth embodiment.

Next, an operation will be discussed.

Adding to the semiconductor integrated circuit with built-in self-test function of the above discussed fourth preferred embodiment, each reload register 8 is provided correspondingly to the respective port registers 4 of the I/O ports to reload a reload value set in advance to the respective corresponding port registers 4 of a plurality of I/O ports in response to the comparison enabling signal.

When tests are simultaneously performed on a plurality of I/O ports, by reloading the reload value to the corresponding port registers 4 of a plurality of I/O ports at the same time in response to the comparison enabling signal, it is made possible to give the reload value to a plurality of I/O ports at the same time and simultaneously perform the tests thereof.

The Sixth Preferred Embodiment

The sixth preferred embodiment uses any one of the semiconductor integrated circuits with built-in self-test function of the above discussed first to fifth preferred embodiments and provides a constitution where the semiconductor integrated circuit with built-in self-test function is incorporated in a system to perform a test on the peripheral function block which the semiconductor integrated circuit with built-in self-test function itself includes when the system is powered-up, reset, under a judgment of abnormal condition or under diagnostics to realize a fail safe function by an early detection of abnormal operation, output of a signal notifying an operation halt due to detection of abnormal condition or a signal notifying an upper level control block of an abnormal condition, or any combination thereof.

With such a constitution, it is made possible to obtain a system which achieves a fail safe function.

What is claimed is:

1. A semiconductor integrated circuit with built-in self-test function comprising:
an I/O port which is programmable and constituted of:
a port direction register physically and logically connected to a terminal;
a port register for storing an output value when said I/O port is an output port;
a port input signal line sharing an address space with said port register; and
a comparator, and
a peripheral function block physically and logically connected to said terminal,
wherein a value for setting said I/O port as said output port is set in said port direction register and the value set in said port register is given to said peripheral function block via said terminal when it is achieved to give an input to said peripheral function block, and
a test judgment is performed when it is achieved to test an output of said peripheral function block, by setting an expected value for said output of said peripheral function block in said port register, and at the same time setting a value for setting said I/O port as an input port in said port direction register and making a comparison between a value output from said peripheral function block via said terminal and said expected value set in said port register with said comparator.

2. The semiconductor integrated circuit with built-in self-test function according to claim 1, wherein an interrupt processing is performed in response to a test judgment result obtained by said comparator.

3. The semiconductor integrated circuit with built-in self-test function according to claim 1, wherein the test judgment result obtained by said comparator is output through an external pin to the outside.

4. The semiconductor integrated circuit with built-in self-test function according to claim 1, wherein permission or non-permission is simultaneously given to a plurality of I/O ports in response to respective values of said port direction registers and a comparison enabling signal when tests are simultaneously performed on said plurality of I/O ports.

5. The semiconductor integrated circuit with built-in self-test function according to claim 4, further comprising
a reload register provided correspondingly to each port register of said I/O ports, wherein the each reload register reload value to each corresponding port register of said plurality of I/O ports in response to said comparison enabling signal when tests are simultaneously performed on said plurality of I/O ports.

6. A system comprising a semiconductor integrated circuit with built-in self-test function, wherein said semiconductor integrated circuit with built-in self-test function as defined in claim 1 is incorporated and performs a test on a peripheral function block which said semiconductor integrated circuit with built-in self-test function itself includes when the system is powered-up, reset, under a judgment of abnormal condition or under diagnostics to realize a fail safe function by an early detection of abnormal operation, output of a signal notifying an operation halt due to detection of abnormal condition or a signal notifying an upper level control block of an abnormal condition, or any combination thereof.
